(19) United States
(12) Patent Application Publication
(10) Pub. No.: US 2020/0377996 A1
(43) Pub. Date: Dec. 3, 2020

(54) DEPOSITION CHAMBER VIEWPORT ASSEMBLY INCLUDING REPLACEABLE TRANSPARENT ROD AND METHOD OF USING SAME

(71) Applicant: BEIJING APOLLO DING RONG SOLAR TECHNOLOGY CO., LTD., Beijing (CN)

(72) Inventors: Steven LAROSA, Santa Clara, CA (US); Thomas HECKEL, Mountain View, CA (US)

(21) Appl. No.: 16/424,963

(22) Filed: May 29, 2019

(51) Int. Cl. C23C 14/52; C23C 14/54

(52) U.S. Cl. CPC C23C 14/52; F16J 15/104; C23C 14/54

(57) ABSTRACT

A deposition chamber includes a chamber wall, an optically transparent rod which extends through an aperture in the wall, such that a first end of the rod is exposed inside of the deposition chamber and an opposing second end of the rod is exposed outside of the deposition chamber, a compression collar which is selectively attached to an outer surface of the wall, such that the collar surrounds the second end of the rod, and a gasket disposed around the rod and compressed by the compression collar, such that the gasket secures the rod in the aperture and generates an air-tight seal.

### FIELD

The present invention is directed to a deposition chamber viewport assembly and method of using the same, and particular, to a viewport assembly including a replaceable transparent rod.

### BACKGROUND

Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂) and any of these compounds with sulfur replacing some of the selenium represent a group of materials, referred to as copper indium selenide CIS based alloys, have desirable properties for use as the absorber layer in thin-film solar cells. To function as a solar absorber layer, these materials should be p-type semiconductors. This may be accomplished by establishing a slight deficiency in copper, while maintaining a chalcopyrite crystalline structure. In CIGS, gallium usually replaces 20% to 35% of the normal indium content to raise the band gap; however, there are significant and useful variations outside of this range. If gallium is replaced by aluminum, smaller amounts of aluminum are used to achieve the same band gap.

### SUMMARY

According to various embodiments of the present disclosure, a deposition chamber includes a chamber wall, an optically transparent rod which extends through an aperture in the wall, such that a first end of the rod is exposed inside of the deposition chamber and an opposing second end of the rod is exposed outside of the deposition chamber, a compression collar which is selectively attached to an outer surface of the wall, such that the collar surrounds the second end of the rod, and a gasket disposed around the rod and compressed by the compression collar, such that the gasket secures the rod in the aperture and generates an air-tight seal.

According to various embodiments of the present disclosure a method of using a deposition chamber viewport assembly includes collecting optical data from inside of the deposition chamber during a deposition process through a viewport assembly comprising an optically transparent rod than extends through a wall of the deposition chamber, stopping the deposition process, removing the rod from the wall without opening the deposition chamber, inserting a reserve rod into the wall without opening the deposition chamber, and restarting the deposition process.

### BRIEF DESCRIPTION OF THE DRAWINGS

FIG. 1 illustrates a planar cross-sectional view of a sputtering apparatus with dual magnetrons according to an embodiment.

FIG. 2A is an enlarged sectional view of the viewport assembly included in the apparatus of FIG. 1, and FIG. 2B is a sectional view of a portion of a deposition chamber wall in which the viewport assembly is inserted.

### DETAILED DESCRIPTION

As set forth herein, various aspects of the disclosure are described with reference to the exemplary embodiments and/or the accompanying drawings in which exemplary embodiments of the invention are illustrated. This invention may, however, be embodied in many different forms and should not be construed as limited to the exemplary embodiments shown in the drawings or described herein. It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It will also be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Ranges can be expressed herein as from “about” one particular value, and/or to “about” another particular value. When such a range is expressed, examples include from the one particular value and/or to the other particular value. Similarly, when values are expressed as approximations, by use of the antecedent “about” or “substantially” it will be understood that the particular value forms another aspect. In some embodiments, a value of “about X” may include values of +/−1% X. It will be further understood that the endpoints of each of the ranges are significant both in relation to the other endpoint, and independently of the other endpoint.

The CIS and CIGS layers of photovoltaic devices may be deposited by evaporation or sputtering. However, it is difficult to make selenium containing sputtering targets. Therefore, when sputter depositing CIS or CIGS layers, a reactive sputtering process is typically used.

In the reactive sputtering process, the deposited layer is formed by a chemical reaction between the target material and a gas which is introduced into the sputtering chamber. To reactively sputter deposit CIS or CIGS, metallic sputtering targets (typically rotating cylinders) of copper-indium or copper-indium-gallium are sputtered in a selenium containing atmosphere. Typically, the atmosphere also contains an inert carrier (or sputtering) gas, such as argon. By varying the relative pressures of the inert and reactive gases, the composition of the deposited layer can be controlled.

The inventors have realized that the composition of plasma generated during a deposition process, such as sputtering, can be monitored with optical techniques such as optical spectrometry. The inventors have further realized that with a feedback mechanism, sputtering process parameters can be varied in-situ to adjust for variations in plasma composition, thereby allowing for the layer deposition, such as deposition of photovoltaic cell CIS and CIGS absorber layers with substantially uniform composition and with substantially uniform electrical properties.

Spectrometer-based monitoring of process conditions generally includes collecting optical data through an optically transparent window into a process chamber. However, deposition processes, such as sputtering, can result in the rapid accumulation of deposition material inside of a deposition chamber, and in particular, on a window of the chamber, which interferes with and/or prevents the collection of optical data through the window. This may be of particular concern for deposition systems that operate continuously for extended periods of time, and may result in hours or even days of lost data. For example, for reactive sputtering deposition of a CIS or CIGS layer, selenium is very reactive and tends to deposit on all surfaces of the deposition chamber, including the window.

In order to restore optical monitoring capability, conventional deposition chambers must be opened and at least partially disabled, in order to access and clean the inner surface of a window, such as to remove selenium from the inner surface of the window. As such, there is a need for an optical system that resists deposition and/or allows for a rapid restoration of optical functionality.

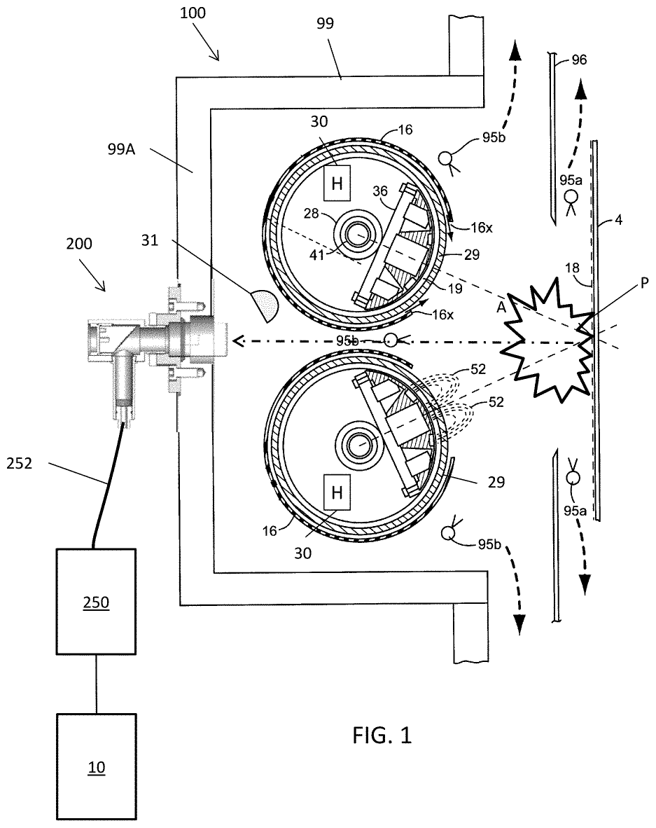

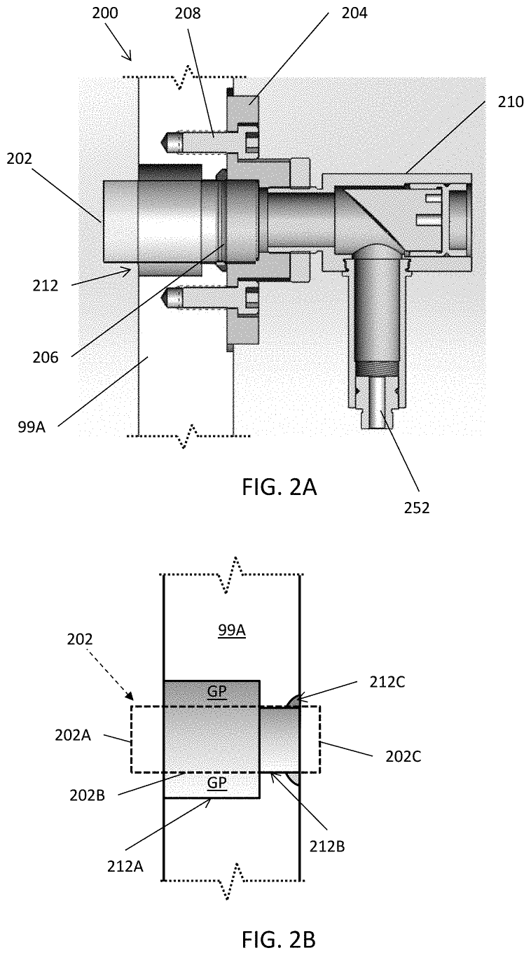

FIG. 1 is a schematic view of a sputter deposition apparatus 100 including a viewport assembly 200 according to an embodiment of the invention. FIG. 2A is an enlarged sectional view of the viewport assembly 200 of FIG. 1, and FIG. 2B is a sectional view of a portion of a deposition chamber wall in which the viewport assembly 200 is inserted.

Referring to FIG. 1, the sputter deposition apparatus 100 may be designed for high rate reactive deposition of CIS or CIGS thin films with conductive target materials. This apparatus 100 includes dual magnetron sputtering target assemblies in a deposition chamber 99 and target protection devices, such as shields 16, to protect the CIG targets from attack by the reactive gas. In an alternative embodiment, the sputter deposition apparatus 10 only includes a single magnetron sputtering target assembly.

Each magnetron target assembly includes a target 29, such as copper indium or copper indium gallium target, a target backing tube 19, a magnet assembly 36, support and water transfer tubes 28 and 41, and shield 16. To deposit CIGS, the sputtering target 29 material typically comprises a copper-indium-gallium alloy and the reactive gas comprises selenium. The sputtering targets 29 are preferably rotating cylinders. The cylinders may be oriented horizontally (the axis of rotation perpendicular to the force of gravity) or vertically (the axis of rotation parallel to the force of gravity).

During the sputtering operation, the target 29 and the target backing tube 19 rotate with respect to magnet assembly 36. Magnet assembly 36 generates arched magnetic fields 52, which the sputtering gas to form a plasma cloud P and sputter the deposition material (e.g., copper, indium and gallium) from the target 29. The deposition material is subsequently deposited on a substrate 4 as a CIGS layer after reacting with the selenium gas in the chamber 99. Substrate 4 is preferably a moving metal web as described in U.S. Pat. Nos. 7,838,763 and 8,115,095, both of which are hereby incorporated by reference in their entirety. Alternatively, the substrate 4 may be stationary. A stationary substrate may be made of metal, polymer or glass.

The shield 16 has a generally clam shell shape with a cutout 16x and may be configured as an electrical anode. As such, the shield 16 may be constructed from a conducting material (usually a metal). Deposition shield 96 prevents high angle, low energy sputtered material from reaching the substrate 4. The heavy dashed arrows indicate the direction of gas flow toward vacuum pumps (not shown) which in this case are attached to a main deposition chamber 99.

Selenium sources 95a, 95b, such as selenium evaporation sources which evaporate selenium into the chamber 99 volume are located adjacent to the target 29. Alternatively, sources 95a and/or 95b may comprise hydrogen selenide gas nozzles or a selenium distribution manifold, as described in U.S. Published Application 2018/0037981 A1, published on Feb. 8, 2018 and incorporated herein by reference in its entirety. The reactive gas (e.g., selenium gas or hydrogen selenide gas) may be introduced near the substrate 4 from sources 95a and/or 95b outside of shields 16.

The viewport assembly 200 may be positioned to receive radiation (e.g., visible light, UV radiation and/or IR radiation) emitted by the plasma cloud P near the substrate 4, as shown by the dashed-dotted arrow in FIG. 1. The viewport assembly 200 may be connected to an optical analyzer 250 by an optical cable 252. The optical analyzer 250 may be configured to generate spectral data using radiation transmitted from the viewport assembly 200 via the optical cable 252. For example, the optical analyzer 250 may comprise a spectrometer.

In various embodiments embodiment, the sputter deposition apparatus 100 includes a controller 10. The controller 10 may be a general or special purpose computer or dedicated control processor or chip. The controller 10 may be connected by a wired or wireless data connection to the optical analyzer 250. In some embodiments, the optical analyzer 250 may be incorporated into the controller 10.

The controller 10 may be configured to provide feedback to various components in the sputter deposition apparatus 100, and thereby control the deposition process by controlling one or more process parameters. Process parameters that may be controlled by the controller 10 include, but are not limited to, the temperature of one or more optional heaters 30 located adjacent to a portion of the sputtering targets 29 or located adjacent to the substrate 4, water temperature/flow rate in conduits 28/41 and/or the flux of reactive vapor (e.g., selenium) from sources 95a and/or 95b. The optional heaters 30 may be located inside of the hollow supports 19 as shown in FIG. 1, embedded in shield 16 as a thin resistive heater, or located outside of but near the shield 16, and/or be located behind the substrate 4.

Referring to FIGS. 1, 2A, and 2B, the viewport assembly 200 may include an optically transparent rod 202, a compression collar 204, a gasket 206, and a collimator 210. The rod 202 may be formed of a heat and abrasion-resistant, low thermal conductivity material, such as transparent quartz or the like. The viewport assembly 200 may be arranged such that the rod 202 is in line-of-sight with the plasma cloud P. Accordingly, the rod 202 may be configured to transmit radiation emitted by the plasma cloud P to the collimator 210. In one embodiment, the rod 202 may have a circular cross sectional shape with a desired diameter perpendicular to its axis and have a three dimensional shape of a cylinder. In alternative embodiments, the rod 202 may have an oval or polygonal cross sectional shape with a desired maximum width perpendicular to its axis. The term “diameter” is used below for the example of a cylindrical rod 202. However, it should be understood that the term “maximum width” may be used instead of “diameter” if the rod 202 has a shape other than that of a cylinder (e.g., if the rod has an oval or polygonal cross sectional shape).

In some embodiments, the rod 202 may be disposed in an aperture 212 that extends through the wall 99A of the deposition chamber 99. The aperture 212 may include a counter bore 212A, a guide bore 212B, and a sealing groove 212C. The diameter of the counter bore 212A may be from about 5% to about 25% larger, such as from about 10% to about 20% larger, than the diameter of the rod 202, such that a gap GP may be formed between the rod and the surface of the counter bore 212A. The guide bore 212B may have a diameter that closely matches the diameter of the rod 202, such as a diameter that is from about 0.01% to about 3% larger, such as from about 0.1% to about 1.5% larger, than the diameter of the rod 202. The gasket 206 may be disposed in the sealing groove 212C. In some embodiments, the gasket 206 may be an O-ring compressive seal, or the like.

As shown in FIG. 2B, a first end 202A of the rod 202 may be disposed in the counter bore 212A. Optionally, the first end 202A of the rod 202 may extend into the interior of the deposition chamber 99 past the inner surface of the wall 99A of the chamber 99. Alternatively, the first end 202A of the rod 202 may terminate in the same plane as or short of the inner surface of the wall 99A of the chamber 99. A middle portion 202B of the rod 202 may be disposed inside of the guide bore 212B and may pass through the gasket 206 and extend into the collar 204. The second end 202C (which is opposite to the first end 202A) of the rod 202 is located in contact with or adjacent to the collimator 210. The collar 204 may be fastened to the wall 99A of the deposition chamber 99 using any suitable type of fastener, such as screws 208, clamp(s), or the like. The collar 204 may be configured to compress the gasket 206 into the groove 212C. The groove 212C may be angled to direct the compressive force applied to the gasket 206 towards the rod 202, such that the gasket 206 is compressed against the rod 202 and an air-tight seal is formed between the deposition chamber wall 99A and the rod 202.

The collar 204, gasket 206, and/or guide bore 212B may be configured to align the rod 202 with the plasma P. The gasket 206 may be configured to hold the rod 202 in position in the wall 99A. For example, friction between the rod 202 and the gasket 206 may be sufficient to prevent the rod 202 from being pulled into the deposition chamber 99 by a vacuum formed therein.

The collimator 210 may be connected to the collar 204 and may be configured to collimate radiation output from the rod 202 and provide the collimated radiation to the spectrometer 250 through an optical fiber of the optical cable 252. The collimator may be a 90° collimator, in some embodiments. However, the present disclosure is not limited thereto.

During a deposition process, heat from hot metal component(s) (e.g., the shields 16, supports and/or other components) inside the deposition chamber 99 may be radiated to the rod 202, such that at least a surface of the first end 202A of the rod 202 may be maintained at a temperature of at least 120° C., such as a temperature ranging from about 120° C. to about 200° C. In some embodiments, the deposition apparatus 100 may include an optional radiative heater 31 configured to heat the rod 202. Thus, the radiative heater and/or hot metal component(s) act as a radiative heat source for the rod 202.

In addition, the walls 99A of the deposition chamber 99 may be maintained at a lower temperature than the rod 202. For example, the walls 99A may be formed of a material having a higher thermal conductivity than that of the rod 202. For example, the walls 99A may be formed of a material having relatively high thermal conductivity, such as aluminum or another metal or alloy, and the rod may be formed of an optically transparent material having a relatively low thermal conductivity, such as quartz, glass, sapphire or the like, which has a lower thermal conductivity than the walls 99A. In some embodiments, the deposition apparatus 100 may include components to actively cool the walls 99A.

Further, the counter bore 212A limits heat conduction between the rod 202 and the wall 99A, since the counter bore 212A reduces direct contact between the wall 99A and the rod 202. Therefore, at least a portion of the rod 202, such as the first end 202A of the rod disposed inside of the deposition chamber 99 may be maintained at a temperature that is from about 40° C. to about 120° C., such as from about 50° C. to about 100° C. higher than a temperature of at least an internal surface of the wall 99A of the deposition chamber 99. Therefore, at least a portion of the rod 202, such as the first end 202A of the rod disposed inside of the deposition chamber 99 may be maintained at a temperature higher than the condensation point of a material the deposition chamber is configured to deposit (e.g., selenium and/or CIGS) and that is higher than a temperature of an inner surface of the wall 99A.

Accordingly, a reactive deposition material, such as selenium in the deposition chamber 99 may be selectively deposited at a higher rate on the relatively cooler walls 99A than on the relatively warmer rod 202. As such, less selenium is deposited on the first end 202A of the rod 202 than on the wall 99A, and thus, the amount of time the rod 202 is sufficiently optically clear to transmit radiation there though may be substantially increased.

Even with the above temperature control, deposition material, such as selenium, may slowly accumulate on the surface of the rod 202 over time. Once the rod 202 is coated with an amount of deposition material that is sufficient to render the rod 202 sufficiently opaque to prevent or interfere with the collection of optical data, the viewport assembly 200 may be serviced.

According to various embodiments of the present disclosure, a method of using the viewport assembly 200 may include using the viewport assembly 200 to collect optical data (e.g., radiation) from the plasma cloud P in the deposition chamber 99 during a deposition process, such as sputtering. During deposition, walls 99A of the deposition chamber 99 may be maintained at a lower temperature than at least a portion of the rod 202, such as the first end 202A of the rod 202 exposed inside of the deposition chamber 99. Optical data may be collected until the rod 202 becomes sufficiently opaque to preclude or interfere with radiation transmission, due to it being coated by a deposition material.

As such, the method may include replacing the coated rod 202 with an uncoated substitute rod. In particular, the collar 204 may be detached from the wall 99A, the coated rod 202 may be extracted from the aperture 212, and a substitute clean rod may be inserted into the aperture 212. The collar 204 may then be reattached to the wall 99A to secure and seal the substitute rod to the wall by compressing the gasket 206. Accordingly, in some embodiments, the viewport assembly may include two or more rods 202, with one of the rods 202 being inserted into the deposition chamber and utilized to transmit radiation and the remaining rod(s) 202 being held in reserve for future use.

In some embodiments, the gasket 206 may also be replaced during this process. In addition, the selenium coated rod 202 may be cleaned on site, or at a separate location, for later reuse. Accordingly, the viewport assembly 200 may be serviced without the need to access the interior of the deposition chamber 99 (e.g., without opening a door or hatch to the interior of the deposition chamber 99), or to wait for the cleaning of the rod. Therefore, the viewport assembly 200 may be more quickly returned to operation, as compared to a conventional viewport having a fixed window.

In one embodiment, the method of using the deposition chamber 99 viewport assembly 200 includes collecting optical data from inside of the deposition chamber 99 during a deposition process (e.g., sputtering) through the viewport assembly 200 comprising an optically transparent rod 202 than extends through a wall 99A of the deposition chamber. The method also includes stopping the deposition process, such as stopping the sputtering process, and removing the rod 202 from the wall 99A through the aperture 212 without opening the deposition chamber 99. In other words, no doors or hatches have to be opened to the deposition chamber 99 to remove the rod 202 through the aperture 212 in the wall 99A, even though the vacuum inside the chamber 99 is preferably broken before the rod 202 is removed. The method also includes inserting a reserve rod into the wall 99A through the aperture 212 without opening the deposition chamber (i.e., without opening a door or hatch to the deposition chamber 99) and restarting the deposition process (e.g., evacuating the deposition chamber 99 using a vacuum pump to place the chamber 99 under vacuum and restarting the sputter deposition process).

During the deposition process, the rod 202 is held in position in the aperture 212 in the wall 99A by the compression collar 204 and the gasket 206 of the viewport assembly 200. The rod 202 is removed from the wall 99A by detaching the compression collar from the outer surface of wall after the rod is coated by a deposition material (e.g., selenium) and rendered substantially opaque. The gasket 206 may be replaced with a reserve gasket which surrounds the reserve rod, and the compression collar 204 may be reattached to the wall after inserting the reserve rod into the wall through the aperture 212. The method may also include removing the deposition material (e.g., selenium) from the original coated rod and utilizing the cleaned rod as an additional reserve rod.

In one embodiment, the deposition process comprises reactive sputtering that generates a plasma cloud P, and collecting the optical data comprises collecting radiation emitted from the plasma cloud P. In one embodiment, the reactive sputtering comprises reactive sputtering of a copper indium gallium selenide layer on a substrate 4 from a copper indium gallium target 29 in a selenium containing ambient using a sputtering gas (e.g., argon) plasma.

While the viewport assembly 200 is shown to be incorporated into a vacuum chamber 99 of a sputtering deposition apparatus 100, the present disclosure is not limited thereto. For example, the viewport assembly 200 may be included in any type of deposition chamber, such as a plasma enhanced chemical vapor deposition chamber, another physical vapor deposition chamber, such as a plasma assisted evaporation or electron beam evaporation chamber, or the like.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

What is claimed is:

1. A deposition chamber, comprising:
a chamber wall;
an optically transparent rod which extends through an aperture in the wall, such that a first end of the rod is exposed inside of the deposition chamber and an opposing second end of the rod is exposed outside of the deposition chamber;
a compression collar which is selectively attached to an outer surface of the wall, such that the collar surrounds the second end of the rod; and
a gasket disposed around the rod and compressed by the compression collar, such that the gasket secures the rod in the aperture and generates an air-tight seal.

2. The deposition chamber of claim 1, further comprising:
a collimator attached to the collar and configured to collimate radiation transmitted through the rod from the inside of the deposition chamber;
an optical cable connected to the collimator; and
optical analyzer configured to generate spectral data using radiation transmitted from the collimator via the optical cable.

3. The deposition chamber of claim 1, wherein the rod is formed of quartz or glass.

4. The deposition chamber of claim 1, wherein the aperture comprises:
a sealing groove formed in the outer surface of the wall, wherein the gasket is located in the sealing groove;
a guide bore that extends from the sealing groove; and
a counter bore that extends from the guide bore to an inner surface of the wall,
wherein the diameter of the counter bore is larger than the diameter of the guide bore.

5. The deposition chamber of claim 4, wherein:
the diameter of the counter bore is from about 5% to about 25% larger than a diameter of the rod, such that a gap is formed between the counter bore and the rod; and
the diameter of the guide bore is from about 0.01% to about 3% larger than the diameter of the rod.

6. The deposition chamber of claim 4, wherein the first end of the rod protrudes inside the deposition chamber past the inner surface of the wall.

7. The deposition chamber of claim 1, further comprising a radiant heat source disposed inside of the deposition chamber and configured to heat the rod, such that at least the first end of the rod is maintained at a temperature that is higher than the condensation point of a material the deposition chamber is configured to deposit and that is higher than a temperature of an inner surface of the wall.

8. The deposition chamber of claim 1, wherein the compression collar is configured to be removed from the wall, such that the rod may be removed from the aperture without accessing the inside of the deposition chamber.

9. The deposition chamber of claim 1, wherein:
the rod comprises a material that has a lower thermal conductivity than the wall; and
the rod has a circular, oval or polygonal cross sectional shape in a direction perpendicular to an axis of the rod.

10. The deposition chamber of claim 1, further comprising:
at least one copper indium or copper indium gallium sputtering target located in the deposition chamber; and
a selenium source located in the deposition chamber.

11. A method of using a deposition chamber viewport assembly, comprising:
collecting optical data from inside of the deposition chamber during a deposition process through a viewport assembly comprising an optically transparent rod than extends through a wall of the deposition chamber;
stopping the deposition process;
removing the rod from the wall without opening the deposition chamber;
inserting a reserve rod into the wall without opening the deposition chamber; and
restarting the deposition process.

12. The method of claim 11, wherein:
the rod is held in position by a compression collar and a gasket of the viewport assembly; and
the rod is removed from the wall by detaching the compression collar from the outer surface of wall after the rod is coated by a deposition material and rendered substantially opaque.

13. The method of claim 12, further comprising removing the deposition material from the coated rod and utilizing the rod as an additional reserve rod.

14. The method of claim 11, further comprising:
replacing the gasket with a reserve gasket which surrounds the reserve rod; and
reattaching the compression collar to the wall after inserting the reserve rod into the wall.

15. The method of claim 11, further comprising radiatively heating at least a portion of the rod to a higher temperature than an inner surface of the wall.

16. The method of claim 15, wherein at least a portion of the rod is maintained at a temperature that is higher than the condensation point of a material the deposition chamber is configured to deposit.

17. The method of claim 11, wherein:
the deposition process comprises reactive sputtering that generates a plasma cloud; and
the collecting optical data comprises collecting radiation emitted from the plasma cloud.

18. The method of claim 17, wherein the reactive sputtering comprises reactive sputtering of a copper indium gallium selenide layer on a substrate from a copper indium gallium target in a selenium containing ambient using a sputtering gas plasma.

19. The method of claim 17, wherein the method further comprises changing deposition parameters based on detected radiation emitted from the plasma cloud.

20. The method of claim 11, wherein the rod comprises a quartz rod which has a circular, oval or polygonal cross sectional shape in a direction perpendicular to an axis of the rod.
